(19) United States
(12) Patent Application Publication
(10) Pub. No.: US 2024/0404962 A1
(43) Pub. Date: Dec. 5, 2024

(54) PACKAGE STRUCTURE AND METHOD FOR FORMING THE SAME

(71) Applicant: Taiwan Semiconductor Manufacturing Company, Ltd., Hsinchu (TW)

(72) Inventors: Pei-Hsuan LO, Hsinchu County (TW); Chih-Ming KE, Hsinchu City (TW); Jeng-Nan HUNG, Taichung City (TW); Chung-Jung WU, Hsinchu City (TW); Yu-Yi HUANG, Taipei City (TW)

(73) Assignee: Taiwan Semiconductor Manufacturing Company, Ltd., Hsinchu (TW)

(21) Appl. No.: 18/329,063

(22) Filed: Jun. 5, 2023

(51) Int. Cl. H01L 23/544; H01L 21/768; H01L 23/00; H01L 23/48; H01L 25/00

(52) U.S. Cl. CPC H01L 23/544; H01L 21/76898; H01L 23/481; H01L 24/32; H01L 25/50; H01L 2223/54426; H01L 2224/32225; H01L 2924/1531

(57) ABSTRACT

A package structure is provided, and includes a first bonding film formed on a first substrate, and a first alignment mark formed in the first bonding film. The first alignment mark includes a plurality of first patterns spaced apart from each other. The package structure includes a second bonding film formed on a second substrate and bonded to the first bonding film, and a second alignment mark formed in the second bonding film. The second alignment mark includes a plurality of second patterns spaced apart from each other. In a top view, the first alignment mark is spaced apart from the second alignment mark, and the distance between adjacent first patterns is less than the distance between the first alignment mark and the second alignment mark.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three dimensional integrated circuits (3DICs) are a recent development in semiconductor packaging in which multiple semiconductor dies are stacked upon one another, such as package-on-package (POP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, for example. However, there are many challenges related to 3DICs.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1D are cross-sectional views illustrating various stages of forming a first alignment mark in accordance with some embodiments of the present disclosure.

FIG. 2A-2B are cross-sectional views illustrating various stages of forming a package structure in accordance with some embodiments of the present disclosure.

FIG. 3A-3C are schematic views illustrating the first alignment mark and the second alignment mark in accordance with some embodiments of the present disclosure.

FIG. 4A-4C are schematic views illustrating the first alignment mark and the second alignment mark in accordance with some embodiments of the present disclosure.

FIG. 5A-5C are schematic views illustrating the first alignment mark and the second alignment mark in accordance with some embodiments of the present disclosure.

FIG. 6A-6C are schematic views illustrating the first alignment mark and the second alignment mark in accordance with some embodiments of the present disclosure.

FIG. 7 is a cross-sectional view illustrating the package structure in accordance with some embodiments of the present disclosure.

FIG. 8 is a cross-sectional view illustrating the package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of package structures and method for forming the same are provided. The package structures include corresponding alignment marks include patterns having an area no larger than 30 μm² on a horizontal plane. Accordingly, the dishing issue that can occur during the planarization process may be reduced. As such, less error may occur for the identification of the patterns of the alignment marks during the subsequent bonding process.

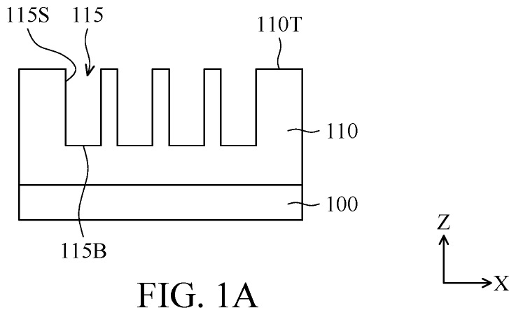

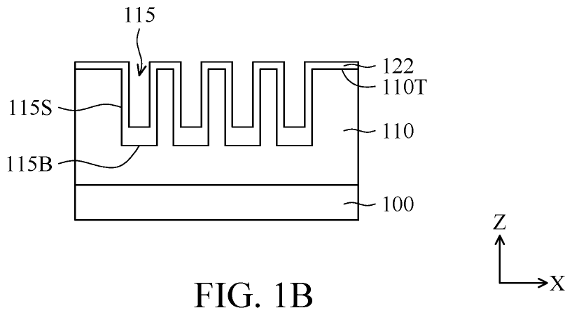

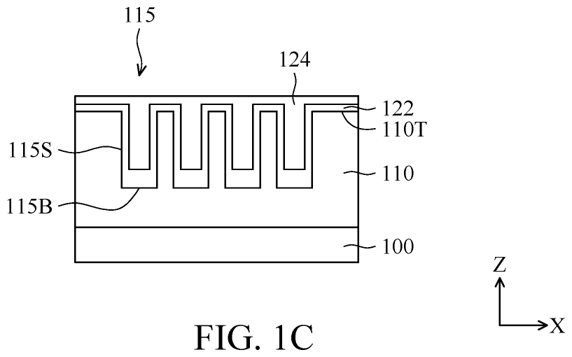

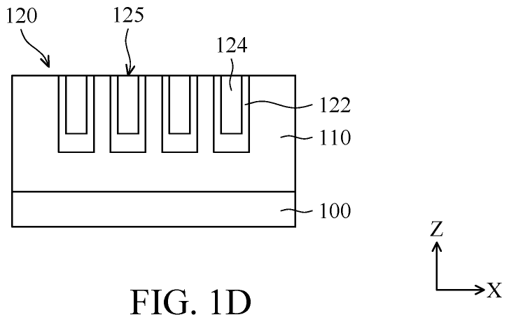

FIGS. 1A-1D are cross-sectional views illustrating various stages of forming a first alignment mark in accordance with some embodiments of the present disclosure. For example, a first substrate 100 includes a semiconductor substrate, including such as silicon, doped or undoped, or an active layer of a semiconductor-on-insulator (SOI) substrate. In some embodiments, the first substrate 100 includes other semiconductor materials, such as germanium; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; or a combination thereof. Other substrates, such as multi-layered or gradient substrates, may also be used.

In addition, a first bonding film 110 is formed over the first substrate 100 for the subsequent bonding process. For example, the material of the first bonding film 110 includes SiON, SiO₂, any other suitable material, or a combination thereof. In some embodiments, a patterned photoresist layer (not shown) is formed over the first bonding film 110. The patterned photoresist layer may be formed by a deposition process and a patterning process. The deposition process for forming the patterned photoresist layer may include a chemical vapor deposition (CVD) process, a high-density plasma chemical vapor deposition (HDPCVD) process, a spin-on process, a sputtering process, or another applicable process. The patterning process for forming the patterned photoresist layer may include a photolithography process and an etching process. The photolithography process may include photoresist coating (e.g., spin-on coating), soft baking, mask aligning, exposure, post-exposure baking, developing the photoresist, rinsing, and drying (e.g., hard baking). The etching process may include a dry etching process or a wet etching process. Then, the first substrate 100 may be recessed by performing an etching process, using the patterned photoresist layer as a mask, and a plurality of first trenches 115 are formed in the first bonding film 110. The etching process may be a dry etching process or a wet etching process. In some embodiments, the dry etching process includes using a fluorine-based etchant gas, such as SF₆, CₓF_{y}, NF₃ or a combination thereof. The etching process may be a time-controlled process. Afterwards, the patterned photoresist layer is removed.

In some embodiments, each of the first trenches 115 has a bottom surface 115B and a sidewall 115S that is connected to the bottom surface 115B. For example, the exemplary sidewall 115S is substantially perpendicular to the bottom surface 115B. However, the present disclosure is not limited thereto. The first trenches 115 are separated from each other by a part of the first bonding film 110. In some embodiments, the part of the first bonding film 110 is sandwiched between the adjacent first trenches 115 in a horizontal direction (for example, parallel to the X axis). In some embodiments, the depth of the first trenches 115 is less than the thickness of the first bonding film 110. That is, the first trenches 115 may not penetrate the first bonding film 110 and expose the underlying first substrate 100. However, the present disclosure is not limited thereto. In some embodiments, the first trenches 115 are formed to have the same width in the direction parallel to the X-Y plane. In some embodiments, the first trenches 115 are formed with a constant interval. Accordingly, the spacing between the first trenches 115 is constant in the direction parallel to the X-Y plane. However, the present disclosure is not limited thereto.

Then, as shown in FIG. 1B, a first dielectric material 122 is deposited in the first trenches 115. In some embodiments, the first dielectric material 122 covers the bottom surface 115B and the sidewall 115S of the first trenches 115, and the top surface 110T of the first bonding film 110 is also covered by the first dielectric material 122. In some embodiments, the first dielectric material 122 is conformally formed on the first bonding film 110, but the present disclosure is not limited thereto. In some embodiments, the thickness of the first dielectric material 122 on the bottom surface 115B of the first trenches 115 is greater than and the thickness of the first dielectric material 122 on the sidewall 115S of the first trenches 115.

For example, the first dielectric material 122 includes one or more sub-dielectric layers formed of materials such as silicon dioxide (SiO₂), Phospho-Silicate Glass (PSG), Boro-Silicate Glass (BSG), Boron-Doped Phospho-Silicate Glass (BPSG), undoped Silicate Glass (USG), or the like. In some embodiments, the first dielectric material 122 is formed, for example, by spin coating, lamination, chemical vapor deposition (CVD), or the like. However, the present disclosure is not limited thereto. Any suitable material and method for the formation of the first dielectric material 122 is contemplated within the scope of the present disclosure.

As shown in FIG. 1C, a first conductive material 124 is deposited in the first trenches 115 and over the first dielectric material 122. For example, the first conductive material 124 include conductive material such as tungsten (W), cobalt (Co), nickel (Ni), copper (Cu), silver (Ag), gold (Au), aluminum (Al), any other suitable conductive material, or a combination thereof. In some embodiments, the first conductive material 124 and the first dielectric material 122 overfill the first trenches 115 and cover the top surface 110T of the first bonding film 110.

As shown in FIG. 1D, a planarization process (such as, chemical mechanical polish (CMP) or any other suitable planarization process) is performed on the first dielectric material 122 and the first conductive material 124. As a result, the top surfaces of the first dielectric material 122 and the first conductive material 124 may be substantially coplanar with the top surface 110T of the first bonding film 110. After the planarization process is completed, a first alignment mark 120 is formed in the first bonding film 110. The first alignment mark 120 includes a plurality of first patterns 125 that are spaced apart from each other. To be more specific, each of first patterns 125 is formed by the first dielectric material 122 and the first conductive material 124 in each first trench 115. That is to say, the first dielectric material 122 and the first conductive material 124 in each of the first trenches 115 define each of first patterns 125.

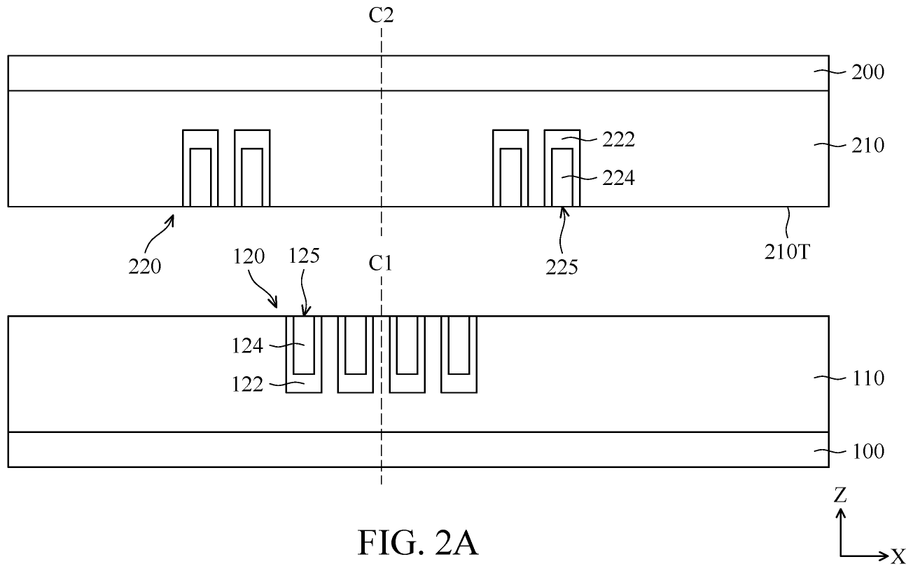

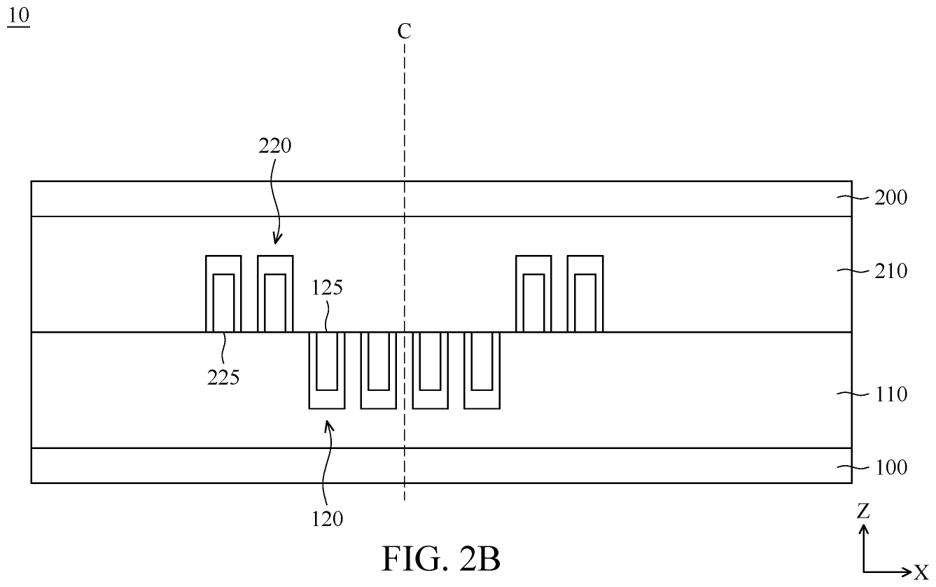

In some embodiments, each of the first patterns 125 has an area no larger than 30 μm² on a horizontal plane (which is, for example, parallel to the top surface 110T of the first bonding film 110). Accordingly, the dishing issue that can occur during the planarization process may be reduced. As such, the top surface of the first conductive material 124 in the first patterns 125 may be less curved and remain coplanar with the top surface 110T of the first bonding film 110. Therefore, less error may occur for the identification of the first patterns 125 during the subsequent bonding process. The detail of the bonding process is further discussed in the following paragraphs in accompany with FIG. 2A-2B.

FIG. 2A-2B are cross-sectional views illustrating various stages of forming a package structure 10 in accordance with some embodiments of the present disclosure. In some embodiments, the package structure 10 is formed by bonding a second substrate 200 to the first substrate 100. As shown in FIG. 2A, the first alignment mark 120 is formed in the first bonding film 110, which is located over the first substrate 100. In addition, a second alignment mark 220 is formed in a second bonding film 210, which is located over the second substrate 200. In some embodiments, the second alignment mark 220 is formed in the second bonding film 210 using the material of method that is the same as that of the first alignment mark 120. For example, a second dielectric material 222 and a second conductive material 224 are filled into a plurality of second trenches 215 in the second bonding film 210. Then, a planarization process performed on the second bonding film 210, and the second alignment mark 220 is formed and includes a plurality of second patterns 225 that are spaced apart from each other. To be more specific, each of second patterns 225 is formed by the second dielectric material 222 and the second conductive material 224 in each second trench 215. That is to say, the second dielectric material 222 and the second conductive material 224 in each of the second trenches 215 define each of second patterns 225.

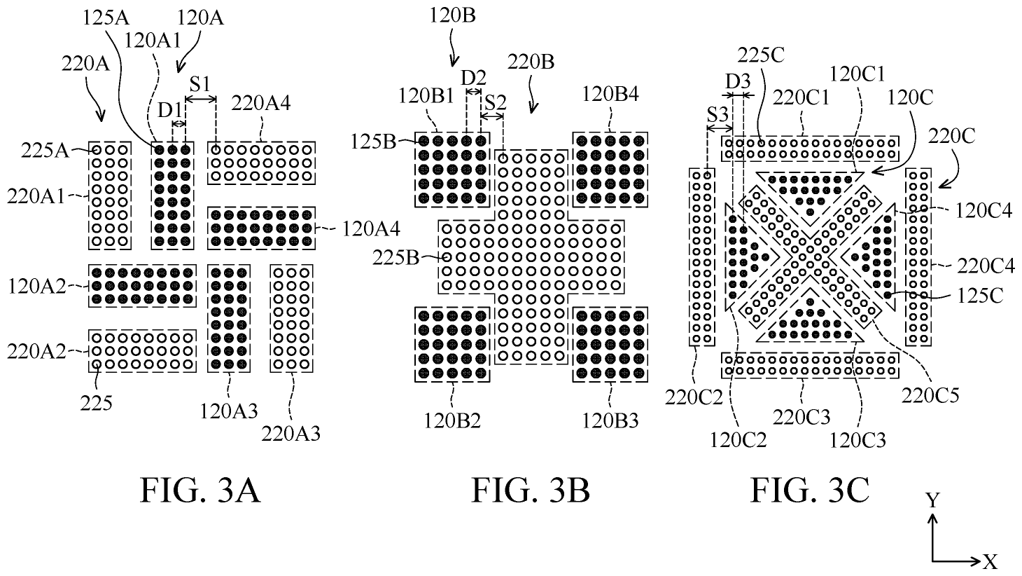

In some embodiments, the first alignment mark 120 has a first center axis C1, and the second alignment mark 220 has a second center axis C2. To be more specific, the first center axis C1 is located at the center point of the whole first alignment mark 120 and perpendicular to the top surface 110T of the first bonding film 110. In some embodiments, the first patterns 125 are formed to be symmetric about the first central axis C1, as shown in FIG. 3A-3C, for example. Similarly, the second center axis C2 is located at the center point of the whole second alignment mark 220 and perpendicular to the top surface 210T of the second bonding film 210. In some embodiments, the second patterns 225 are formed to be symmetric about the second central axis C2.

As shown in FIG. 2A, before the second substrate 200 is bonded to the first substrate 100, the first central axis C1 of the first alignment mark 120 is aligned with the second central axis C2 of the second alignment mark 220. Then, as shown in FIG. 2B, after it is determined that the first central axis C1 of the first alignment mark 120 is coincident with the second central axis C2 of the second alignment mark 220, the second substrate 200 is moved towards the first substrate 100, and the first bonding film 110 is combined with (for example, in contact with) the second bonding film 210. In the present embodiment, the first central axis C1 and the second central axis C2 are integrated together as the central axis C. In some embodiments, the first alignment mark 120 is mismatched with the second alignment mark 220 in a horizontal direction (which is, for example, parallel to the central axis). With the arrangement of the first alignment mark 120 and the second alignment mark 220, the process time and cost for bonding the first substrate 100 and the second substrate 200 may be reduced.

FIG. 3A-3C are schematic views illustrating the first alignment marks 120A-120C and the second alignment mark 220A-220C in accordance with some embodiments of the present disclosure. As shown in FIG. 3A, the first alignment mark 120A includes a plurality of sub-alignment marks 120A1, 120A2, 120A3, and 120A4, and each of which comprises a plurality of first patterns 125A. Correspondingly, the second alignment mark 220A includes a plurality of sub-alignment marks 220A1, 220A2, 220A3, and 220A4, each of which comprises a plurality of second patterns 225A. In the present embodiments, the sub-alignment marks 120A1, 120A2, 120A3, and 120A4 may have a rectangular profile, and so as the sub-alignment marks 220A1, 220A2, 220A3, and 220A4. In some embodiments, in the top view, the area of each of the first patterns 125A and second patterns 225A is about 0.1 μm² to about 30 μm². As set forth above, these first patterns 125A of the first alignment mark 120A may reduce the dishing issue that can occur during the planarization process, improving accuracy for identifying and aligning the first alignment mark 120A (with the second alignment mark 220A).

In the present embodiment, the first alignment mark 120A is spaced apart from the second alignment mark 220A, and the first alignment mark 120A and the second alignment mark 220A are arranged around the central axis C. In the present embodiment, the distance D1 between adjacent first patterns 125A is less than the distance S1 between the first alignment mark 120A and the second alignment mark 220A, which helps to determine the boundaries of the first alignment mark 120A and the second alignment mark 220A. In some embodiments, the distance S1 between the first alignment mark 120A and the second alignment mark 220A may be ranged from about 2 μm to about 3 μm. However, the present disclosure is not limited thereto.

As shown in FIG. 3B, the first alignment mark 120B includes a plurality of sub-alignment marks 120B1, 120B2, 120B3, and 120B4, and each of which includes a plurality of first patterns 125B. In the present embodiments, the first patterns 125B may have a rectangular profile. Correspondingly, the second alignment mark 220B includes a plurality of second patterns 225B that are located among the sub-alignment marks 120B1, 120B2, 120B3, and 120B4, and the second patterns 225 may be collectively viewed as a cross profile.

In the present embodiment, the first alignment mark 120B is spaced apart from the second alignment mark 220B, and the first alignment mark 120B and the second alignment mark 220B are arranged around the central axis C. In the present embodiment, the distance D2 between adjacent first patterns 125B is shorter than the distance S2 between the first alignment mark 120B and the second alignment mark 220B, which helps to determine the boundaries of the first alignment mark 120B and the second alignment mark 220B.

As shown in FIG. 3C, the first alignment mark 120C includes a plurality of sub-alignment marks 120C1, 120C2, 120C3, and 120C4, each of which includes a plurality of first patterns 125C. In the present embodiments, the first patterns 125C may have a triangular profile. Correspondingly, the second alignment mark 220C includes a plurality of sub-alignment marks 220C1, 220C2, 220C3, 220C4, and 220C5, and each of which includes a plurality of second patterns 225C that are located around the sub-alignment marks 120C1, 120C2, 120C3, and 120C4.

In the present embodiment, the first alignment mark 120C is spaced apart from the second alignment mark 220C, and the first alignment mark 120C and the second alignment mark 220C are arranged around the central axis C. In the present embodiment, the distance D3 between adjacent first patterns 125C is shorter than the distance S3 between the first alignment mark 120C and the second alignment mark 220C, which helps to determine the boundaries of the first alignment mark 120C and the second alignment mark 220C.

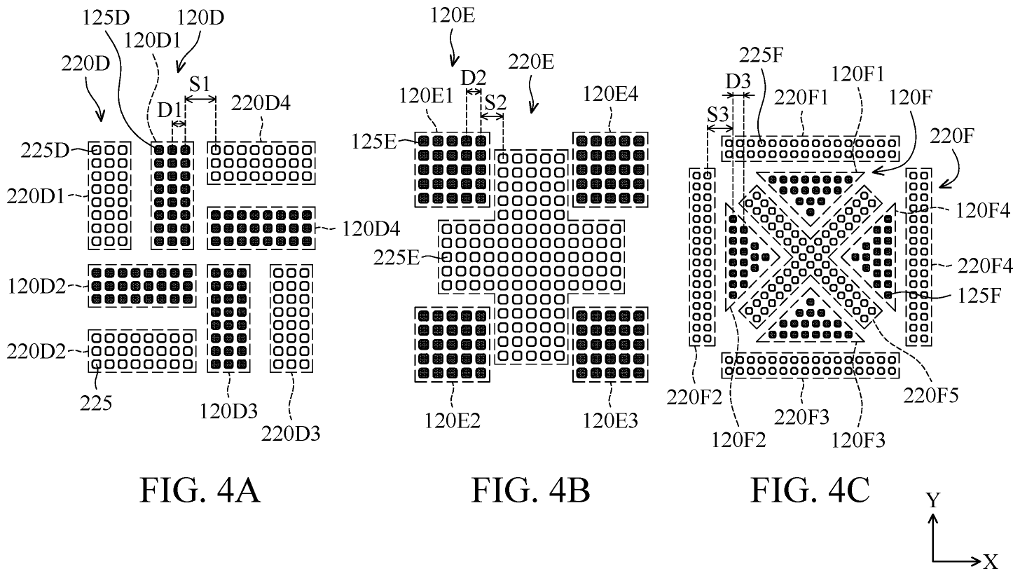

FIG. 4A-4C are schematic views illustrating the first alignment marks 120D-120F and the second alignment marks 220D-220F in accordance with some embodiments of the present disclosure. It should be noted that the first alignment marks 120D-120F and the second alignment marks 220D-220F in the present embodiment may include elements that are the same or similar to the first alignment marks 120A-120C and the second alignment marks 220A-220C shown in FIG. 3A-3C. These elements are denoted by the same or similar numerals and will not be discussed in detail in the following paragraphs. As shown in FIG. 4A-4C, the first patterns 125D-125F in the first alignment marks 120D-120F and the second patterns 225D-225F in the second alignment marks 220D-220F may have the shape of a rounded rectangle.

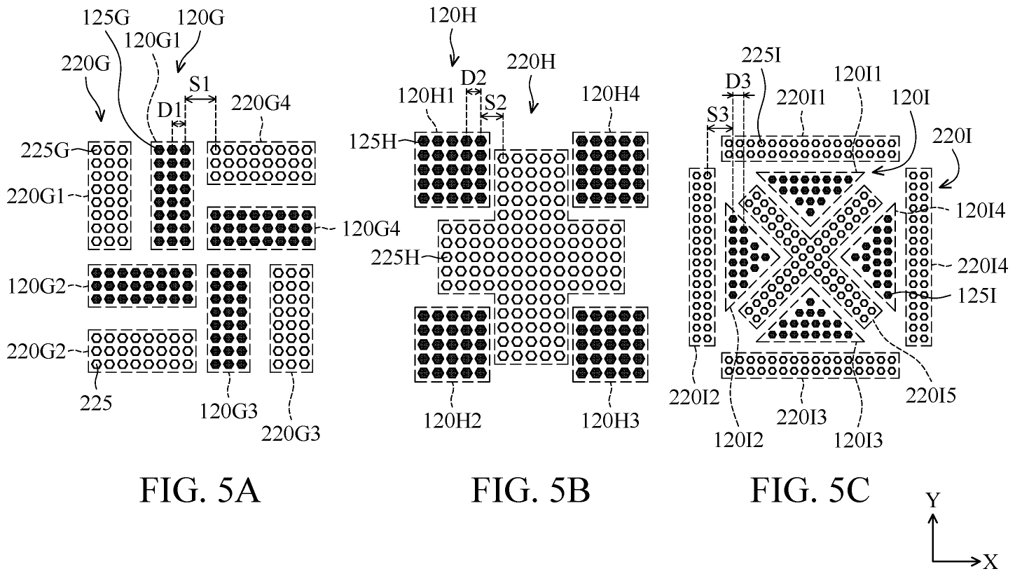

FIG. 5A-5C are schematic views illustrating the first alignment mark 120G-120I and the second alignment mark 220G-220I in accordance with some embodiments of the present disclosure. It should be noted that the first alignment marks 120G-120I and the second alignment marks 220G-2201 in the present embodiment may include elements that are the same or similar to the first alignment marks 120A-120C and the second alignment marks 220A-220C shown in FIG. 3A-3C. These elements are denoted by the same or similar numerals and will not be discussed in detail in the following paragraphs. As shown in FIG. 5A-5C, the first patterns 125G-1251 in the first alignment marks 120G-1201 and the second patterns 225D-225F in the second alignment marks 220G-220I may have the shape of a hexagon. It should be noted that other kinds of polygons may be contemplated within the scope of the present disclosure.

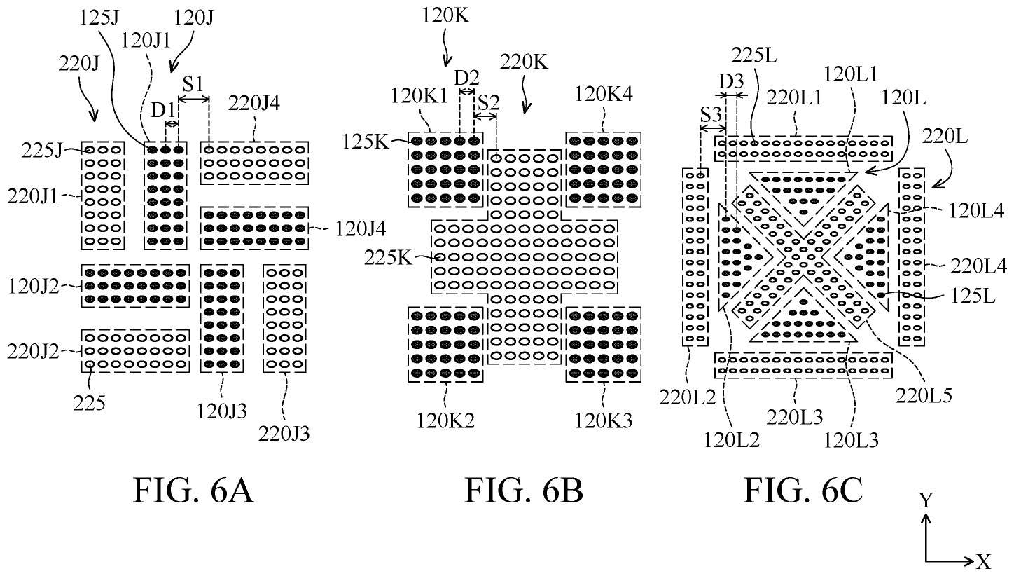

FIG. 6A-6C are schematic views illustrating the first alignment mark 120J-120L and the second alignment mark 220J-220L in accordance with some embodiments of the present disclosure. It should be noted that the first alignment marks 120J-120L and the second alignment marks 220J-220L in the present embodiment may include elements that are the same or similar to the first alignment marks 120A-120C and the second alignment marks 220A-220C shown in FIG. 3A-3C. These elements are denoted by the same or similar numerals and will not be discussed in detail in the following paragraphs. As shown in FIG. 6A-6C, the first patterns in the first alignment marks 120J-120L and the second patterns in the second alignment marks 220J-220L may have the shape of an ellipse.

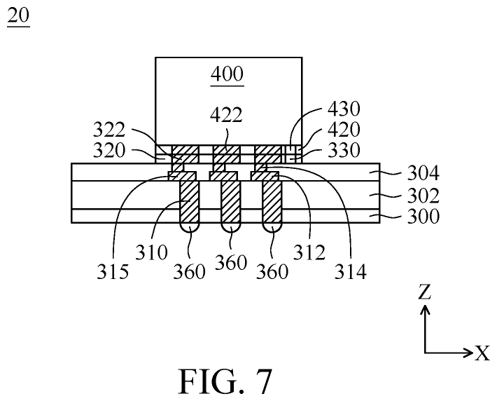

FIG. 7 is a cross-sectional view illustrating the package structure 20 in accordance with some embodiments of the present disclosure. For example, a first package component 300 includes a semiconductor substrate, including such as silicon, doped or undoped, or an active layer of a semiconductor-on-insulator (SOI) substrate. In some embodiments, the first package component 300 includes other semiconductor materials, such as germanium; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; or a combination thereof. Other substrates, such as multi-layered or gradient substrates, may also be used.

In some embodiments, an interconnect structure 315 is formed in the first package component 300. In some embodiments, the interconnect structure 315 includes a plurality of through-silicon via (TSV) structures 310, a plurality of metallization patterns 312, and a plurality of conductive features 314. In some embodiments, the TSV structures 310 are formed in the first package component 300 and a dielectric layer 302 formed on the first package component 300. However, the present disclosure is not limited thereto. In some other embodiments, the dielectric layer 302 may be omitted, and the TSV structures 310 are completely located in the first package component 300.

In some embodiments, the dielectric layer 302 includes one or more sub-dielectric layers formed of materials such as silicon dioxide (SiO₂), Phospho-Silicate Glass (PSG), Boro-Silicate Glass (BSG), Boron-Doped Phospho-Silicate Glass (BPSG), undoped Silicate Glass (USG), or the like. In some embodiments, the dielectric layer 302 is formed, for example, by spin coating, lamination, chemical vapor deposition (CVD), or the like.

In some embodiments, the formation of the TSV structures 310 includes forming a plurality of trenches in the first package component 300. In some embodiments, the trenches extend into the first package component 300 and penetrate the dielectric layer 302 (if present) to electrically and physically couple the overlying metallization patterns 312. In some other embodiments, the TSV structures 310 may have a rectangular profile in the cross-sectional view. In some embodiments, the TSV structures 310 are formed of tungsten (W), cobalt (Co), nickel (Ni), copper (Cu), silver (Ag), gold (Au), aluminum (Al), any other suitable conductive material, or a combination thereof. However, the present disclosure is not limited thereto.

The metallization patterns 312 and the conductive features 314 are surrounded by a dielectric layer 304 for proper insulation, reducing the probability of forming short-circuit. In some embodiments, the dielectric layer 304 includes one or more sub-dielectric layers formed of materials such as silicon dioxide (SiO₂), Phospho-Silicate Glass (PSG), Boro-Silicate Glass (BSG), Boron-Doped Phospho-Silicate Glass (BPSG), undoped Silicate Glass (USG), or the like. In some embodiments, the dielectric layer 304 is formed, for example, by spin coating, lamination, chemical vapor deposition (CVD), or the like. In some embodiments, the dielectric layer 304 is formed by using material or method that is the same as that of the dielectric layer 302. However, the present disclosure is not limited thereto. In some embodiments, the dielectric layer 304 is formed by using material or method that is different from that of the dielectric layer 302.

In some embodiments, one or more devices (not individually shown) are in the formed in first package component 300 or the overlying dielectric layers 302, 304, and electrically connected to the TSV structures 310, the metallization patterns 312, and/or the conductive features 314. In some embodiments, the devices are active devices (e.g., transistors, diodes, etc.), capacitors, resistors, etc. For example, the devices are metal-oxide-semiconductor field-effect transistor (MOSFET), in accordance with some embodiments of the present disclosure.

In some embodiments, the metallization patterns 312 include metal lines and the conductive features 314 include vias formed in the dielectric layer 304. For example, the metallization patterns 312 and/or the conductive features 314 include conductive material such as tungsten (W), cobalt (Co), nickel (Ni), copper (Cu), silver (Ag), gold (Au), aluminum (Al), any other suitable conductive material, or a combination thereof. In some embodiments, the TSV structures 310, the metallization patterns 312, and/or the conductive features 314 are formed of the same material. In some other embodiments, the TSV structures 310, the metallization patterns 312, and/or the conductive features 314 are formed of different materials.

Accordingly, the TSV structures 310 is electrically connected to the metallization patterns 312 and the conductive features 314 for forming a conductive path connected to external environment (e.g. another semiconductor die or external devices). For example, when the devices in the first package component 300 are transistors, the TSV structures 310 may couple the gates or source/drain regions of the transistors. Source/drain regions may refer to a source or a drain, individually or collectively dependent upon the context.

In addition, a bonding film 320 is formed over the first package component 300 for the bonding process. For example, the material of the bonding film 320 includes SiON, SiO₂, any other suitable material, or a combination thereof. In some embodiments, a plurality of bonding pads 322 are formed in the bonding film 320. For example, the bonding pads 322 include conductive material such as tungsten (W), cobalt (Co), nickel (Ni), copper (Cu), silver (Ag), gold (Au), aluminum (Al), any other suitable conductive material, or a combination thereof. In some embodiments, the bonding pads 322 are formed corresponding to a second package component 400. However, the present disclosure is not limited thereto. In some embodiments, a first alignment mark 330 may be formed in the bonding film 320 and adjacent to the bonding pads 322. The first alignment mark 330 may be selected from the first alignment mark 120A-120L shown in the present disclosure. However, all the possible alignment marks formed by the method shown in FIG. 1A-1D are contemplated within the scope of the present disclosure.

In some embodiments, a second package component 400 is bonded over the first package component 300. For example, the second package component 400 may be a device die, a package with a device die(s) packaged therein, a System-on-Chip (SoC) die including a plurality of device dies packaged as a system, or the like. The second package component 400 may be or may comprise logic dies, memory dies, input-output dies, Integrated Passive Devices (IPDs), or the like, or combinations thereof. For example, the logic device dies in the second package component 400 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in the second package component 400 may include Static Random Access Memory (SRAM) dies, Dynamic Random Access Memory (DRAM) dies, or the like. The second package component 400 may include semiconductor substrates and interconnect structures, which are not individually shown in the present embodiment.

In addition, another bonding film 420 is formed on the second package component 400 for the bonding process. For example, the material of the bonding film 420 includes SiON, SiO₂, any other suitable material, or a combination thereof. In some embodiments, the material of the bonding film 420 is the same as the material of the bonding film 320. Although two bonding films (e.g. the bonding film 320 and the bonding film 420) are shown in the present disclosure, it should be appreciated that one or multiple (more than two) bonding films are also adopted in the present disclosure.

In some embodiments, a plurality of bonding pads 422 are formed in the bonding film 420. For example, the bonding pads 422 include conductive material such as tungsten (W), cobalt (Co), nickel (Ni), copper (Cu), silver (Ag), gold (Au), aluminum (Al), any other suitable conductive material, or a combination thereof. In some embodiments, the bonding pads 422 are each aligned with the bonding pads 322 over the first package component 300 to form electrical connection between the second package component 400 and the interconnect structure 315. In some embodiments, a second alignment mark 430 may be formed in the bonding film 420 and adjacent to the bonding pads 422. The second alignment mark 430 may be selected from the second alignment mark 220A-220L shown in the present disclosure. However, all the possible alignment marks formed by the method shown in FIG. 1A-1D are contemplated within the scope of the present disclosure. In some embodiments, the second alignment mark 430 is aligned with the first alignment mark 330 to facilitate the bonding process.

In some embodiments, a plurality of bump structures 360 are formed on the exposed TSV structures 310. That is, the bump structures 360 are formed on the first package component 300 and cover the exposed surfaces of the TSV structures 310. In some embodiments, the bump structures 360 may include controlled collapse chip connection (C4) bumps, solder bumps, copper bumps, micro bumps, electroless nickel-electroless palladium-immersion gold technique (ENEPIG) formed bumps, ball grid array (BGA) bumps, copper pillars, or the like.

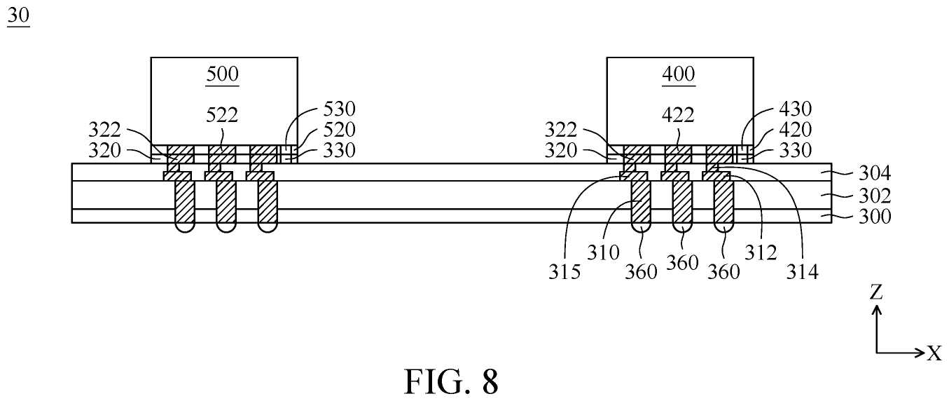

FIG. 8 is a cross-sectional view illustrating the package structure 30 in accordance with some embodiments of the present disclosure. It should be noted that the package structure 30 in the present embodiment may include elements that are the same or similar to the package structure 20 shown in FIG. 7. These elements are denoted by the same or similar numerals and will not be discussed in detail in the following paragraphs. As shown in FIG. 8, the package structure 30 includes a first package component 300, an interconnect structure 315 in the first package component 300, and a second package component 400. The second package component 400 is bonded over the first package component 300 via multiple bonding films 120 and 140.

In some embodiments, a third package component 500 is bonded over the first package component 300. For example, the third package component 500 may be a device die, a package with a device die(s) packaged therein, a System-on-Chip (SoC) die including a plurality of device dies packaged as a system, or the like. The third package component 500 may be or may comprise logic dies, memory dies, input-output dies, Integrated Passive Devices (IPDs), or the like, or combinations thereof. For example, the logic device dies in the third package component 500 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in the third package component 500 may include Static Random Access Memory (SRAM) dies, Dynamic Random Access Memory (DRAM) dies, or the like. The third package component 500 may include semiconductor substrates and interconnect structures, which are not individually shown in the present embodiment.

In addition, another bonding film 520 is formed on the third package component 500 for the bonding process. For example, the material of the bonding film 520 includes SiON, SiO₂, any other suitable material, or a combination thereof. In some embodiments, the material of the bonding film 520 is the same as the material of the bonding film 320. Although two bonding films (e.g. the bonding film 320 and the bonding film 520) are shown in the present disclosure, it should be appreciated that one or multiple (more than two) bonding films are also adopted in the present disclosure.

In some embodiments, a plurality of bonding pads 522 are formed in the bonding film 520. For example, the bonding pads 522 include conductive material such as tungsten (W), cobalt (Co), nickel (Ni), copper (Cu), silver (Ag), gold (Au), aluminum (Al), any other suitable conductive material, or a combination thereof. In some embodiments, the bonding pads 522 are each aligned with the bonding pads 322 over the first package component 300 to form electrical connection between the third package component 500 and the interconnect structure 315.

In some embodiments, a third alignment mark 530 may be formed in the bonding film 520 and adjacent to the bonding pads 522. The third alignment mark 530 may be selected from the second alignment mark 220A-220L shown in the present disclosure. However, all the possible alignment marks formed by the method shown in FIG. 1A-1D are contemplated within the scope of the present disclosure. In some embodiments, the third alignment mark 530 is aligned with the first alignment mark 330 to facilitate the bonding process. In some embodiments, the third alignment mark 530 is different from the second alignment mark 430 to reduce the risk that the third package component 500 and/or the second package component 400 is mounted on wrong positions.

As described above, the present disclosure is directed to package structures and methods for forming the same. The package structures include corresponding alignment marks include patterns having an area no larger than 30 μm² on a horizontal plane. Accordingly, the dishing issue that can occur during the planarization process may be reduced. As such, less error may occur for the identification of the patterns of the alignment marks during the subsequent bonding process. In addition, the distance between adjacent patterns in the first alignment mark is shorter than the distance between the first alignment mark and the second alignment mark, which helps to determine the boundaries of the first alignment mark and the second alignment mark. Furthermore, different alignment marks may be adopted for different package components for reducing the risk of incorrect installation of the package components.

In accordance with some embodiments, a package structure is provided and includes a first bonding film formed on a first substrate, and a first alignment mark formed in the first bonding film. The first alignment mark includes a plurality of first patterns spaced apart from each other. The package structure includes a second bonding film formed on a second substrate and bonded to the first bonding film, and a second alignment mark formed in the second bonding film. The second alignment mark includes a plurality of second patterns spaced apart from each other. In a top view, the first alignment mark is spaced apart from the second alignment mark, and the distance between adjacent first patterns is shorter than the distance between the first alignment mark and the second alignment mark.

In accordance with some embodiments, a method of forming a package structure in provided and includes forming a first bonding film on a first substrate. The method includes forming a first alignment mark in the first bonding film. The first alignment mark includes a plurality of first patterns spaced apart from each other. The method includes forming a second bonding film on a second substrate. The method includes forming a second alignment mark in the second bonding film. The second alignment mark includes a plurality of second patterns spaced apart from each other. The method includes aligning the second substrate with the first substrate by aligning a first central axis of the first alignment mark with a second central axis of the second alignment mark. The distance between adjacent first patterns is shorter than the distance between one of the first patterns and one of the second patterns in a direction perpendicular to the first central axis. The method also includes bonding the second substrate to the first substrate.

In accordance with some embodiments, a package structure is provided and includes a first bonding film on a first package component and a second bonding film on a second package component. A plurality of first trenches are formed in the first bonding film, a first plurality and a second plurality of first patterns are formed by a first dielectric material and a first conductive material filled in the first trenches, and a distance between two adjacent first patterns in the first plurality of the first patterns is less than a distance between one of the first plurality of the first patterns and one of the second plurality of the first patterns. A plurality of second trenches are formed in the second bonding film, and a plurality of second patterns are formed by a second dielectric material and a second conductive material filled in the second trenches. The second package component is bonded to the first package component via the first bonding film and the second bonding film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first bonding film formed on a first substrate;
a first alignment mark formed in the first bonding film, wherein the first alignment mark comprises a plurality of first patterns spaced apart from each other;
a second bonding film formed on a second substrate and bonded to the first bonding film; and
a second alignment mark formed in the second bonding film, wherein the second alignment mark comprises a plurality of second patterns spaced apart from each other,
wherein in a top view, the first alignment mark is spaced apart from the second alignment mark, and a distance between adjacent first patterns is less than a distance between the first alignment mark and the second alignment mark.

2. The package structure as claimed in claim 1, wherein each of the first patterns comprises:
a dielectric layer provided within the first bonding film; and
a metal layer provided within the first bonding film so that the dielectric layer is disposed between the metal layer and the bonding film, wherein a top surface of the metal layer is substantially level with a top surface of the first bonding film.

3. The package structure as claimed in claim 1, wherein the first patterns and the second patterns are symmetrically arranged around a central axis, and the central axis is perpendicular to a top surface of the first substrate.

4. The package structure as claimed in claim 3, wherein the central axis is spaced apart from the first alignment mark and the second alignment mark in the top view.

5. The package structure as claimed in claim 1, wherein in the top view, either of the first patterns or the second patterns has a shape of a circle, an ellipse, a rounded rectangle, or a polygon.

6. The package structure as claimed in claim 1, wherein in the top view, each of the first patterns and second patterns has an area of about 0.1 μm² to about 30 μm².

7. A method of forming a package structure, comprising:
forming a first bonding film on a first substrate;
forming a first alignment mark in the first bonding film, wherein the first alignment mark comprises a plurality of first patterns spaced apart from each other;
forming a second bonding film on a second substrate;
forming a second alignment mark in the second bonding film, wherein the second alignment mark comprises a plurality of second patterns spaced apart from each other;
aligning the second substrate with the first substrate by aligning a first central axis of the first alignment mark with a second central axis of the second alignment mark, wherein a distance between adjacent first patterns is less than a distance between one of the first patterns and one of the second patterns in a direction perpendicular to the first central axis; and
bonding the second substrate to the first substrate.

8. The method as claimed in claim 7, wherein forming the first alignment mark comprises forming the first patterns symmetrically about the first central axis.

9. The method as claimed in claim 7, wherein a top surface of the first alignment mark is substantially coplanar with a top surface of the first bonding film.

10. The method as claimed in claim 7, wherein after bonding the second substrate to the first substrate, the first alignment mark is mismatched with the second alignment mark in a direction parallel to the first central axis.

11. The method as claimed in claim 7, wherein forming the first alignment mark in the first bonding film comprises:
forming a plurality of first trenches in the first bonding film;
filling a first dielectric material and a first conductive material in the first trenches; and
performing a planarization process on the first dielectric material and the first conductive material.

12. The method as claimed in claim 11, wherein the first trenches are formed to have the same width.

13. The method as claimed in claim 11, wherein the first dielectric material covers a bottom surface and sidewalls of the first trenches.

14. A package structure, comprising:
a first bonding film on a first package component, wherein a plurality of first trenches are formed in the first bonding film, a first plurality and a second plurality of first patterns are formed by a first dielectric material and a first conductive material filled in the first trenches, and a distance between two adjacent first patterns in the first plurality of the first patterns is less than a distance between one of the first plurality of the first patterns and one of the second plurality of the first patterns; and
a second bonding film on a second package component, wherein a plurality of second trenches are formed in the second bonding film, and a plurality of second patterns are formed by a second dielectric material and a second conductive material filled in the second trenches,
wherein the second package component is bonded to the first package component via the first bonding film and the second bonding film.

15. The package structure as claimed in claim 14, wherein the distance between two adjacent first patterns in the first plurality of the first patterns is about 0.1 μm to about 2 μm.

16. The package structure as claimed in claim 14, wherein an area of each of the first trenches is not greater than 30 μm² on a plane parallel to a top surface of the first package component.

17. The package structure as claimed in claim 14, wherein a depth of the first trenches is less than a thickness of the first bonding film.

18. The package structure as claimed in claim 14, further comprising:
a third bonding film on a third package component, wherein a plurality of third trenches are formed in the third bonding film, and a plurality of third patterns are formed by a third dielectric material and a third conductive material filled in the third trenches,
wherein the third package component is bonded to the first package component via the first bonding film and the third bonding film.

19. The package structure as claimed in claim 18, wherein an area of the third patterns is different from an area of the second patterns on a top surface of the first bonding film.

20. The package structure as claimed in claim 14, wherein the first bonding film further comprises a first bonding pad disposed adjacent to the first patterns, and the second bonding film further comprises a second bonding pad aligned with the first bonding pad.
